(19) United States
(12) Patent Application Publication
(10) Pub. No.: US 2025/0157905 A1
(43) Pub. Date: May 15, 2025

(54) INTERPOSER AND METHOD FOR MANUFACTURING INTERPOSER

(71) Applicant: NGK INSULATORS, LTD., Nagoya-shi (JP)

(72) Inventors: Yoshitsugu WAKAZONO, Nagoya-shi (JP); Makoto TANI, Inazawa-shi (JP)

(21) Appl. No.: 19/023,530

(22) Filed: Jan. 16, 2025

Related U.S. Application Data
(63) Continuation of application No. PCT/JP2022/029224, filed on Jul. 29, 2022.

(51) Int. Cl. H01L 23/498; H01L 21/48; H10D 1/20

(52) U.S. Cl. CPC H01L 23/49827; H01L 21/486; H01L 23/49838; H01L 23/49894; H10D 1/20

(57) ABSTRACT

A conductor portion extends through a through hole of an insulator substrate, and is made of a sintered material including sintered metal. A magnetic material portion surrounds the conductor portion within the through hole, is made of ceramics, is inorganically bonded to the conductor portion, and constructs an inductor with the conductor portion. A wiring portion includes a connecting via having a bottom surface electrically connected to the conductor portion. The bottom surface of the connecting via is spaced apart from the magnetic material portion.

### CROSS-REFERENCE TO RELATED APPLICATION

This application is a continuation application of PCT/JP2022/029224, filed on Jul. 29, 2022, the entire contents of which are incorporated herein by reference.

### BACKGROUND OF THE INVENTION

### Field of the Invention

The present invention relates to an interposer and a method for manufacturing the interposer and, in particular, to an interposer with a built-in inductor for mounting thereto a semiconductor element and a method for manufacturing the interposer.

### Description of the Background Art

According to Japanese Patent Application Laid-Open No. 2019-179792, an interposer is disposed between a semiconductor element and a motherboard in a semiconductor device. The interposer and each of the semiconductor element and the motherboard are connected using solder balls. A multilayer wiring printed board is shown as the interposer, and includes a core substrate, three conductor circuit layers stacked over the core substrate to face the semiconductor element, and three conductor circuit layers stacked over the core substrate to face the motherboard. On a side of the interposer where the semiconductor element is mounted, a wiring dimension is reduced in stages by passing through the three conductor circuit layers.

Efficient power management is sometimes required for a semiconductor element for an integrated circuit (IC), for example. A supply voltage to each of a plurality of computing cores of a processor chip (the semiconductor element) is typically controlled by a voltage regulator in response to an amount of computation of a processor and the like. A switch, a capacitor, and an inductor are normally required to construct the voltage regulator. The switch, the capacitor, and the inductor are required for each of the computing cores to control the supply voltage for each of the computing cores. In particular, the inductor is difficult to be built in the semiconductor element, and thus is normally prepared separately from the semiconductor element. Use of a magnetic material is proposed to secure a sufficient inductance while suppressing a footprint for the inductor.

US Patent Application Publication No. 2019/0279806 discloses a package substrate (a kind of interposer herein) disposed between a die (the semiconductor element) and a board (the motherboard). An inductor for the above-mentioned purpose is built in the package substrate. Specifically, the package substrate includes a substrate core, a conductive through hole through the substrate core, and a magnetic sheath around the conductive through hole. The magnetic sheath may include magnetic particles. The substrate core may be any substrate on which build-up layers (the conductor circuit layers) are formed. An organic material is shown as an example of a material for the core substrate.

WO 2007/129526 discloses a core substrate in which an inductor is disposed. As a method for manufacturing the inductor, a through hole is formed in an axial direction of a longitudinally extending magnetic body, and a conductor is formed on an inner surface of the through hole by metal plating. The conductor is formed to be hollow to release a stress caused by a difference in thermal expansion between the conductor and the magnetic body. As a method for embedding the inductor in the substrate, a through hole is formed in the substrate, the inductor is inserted into the through hole, and a space between the inductor and the substrate is filled with a resin.

In the above, some features related to the patent documents, namely, Japanese Patent Application Laid-Open No. 2019-179792, US Patent Application Publication No. 2019/0279806 and WO 2007/129526, have been outlined.

A plurality of computing cores have recently been mounted to a die (the semiconductor element) to be joined to an interposer. In particular, a high-performance processor, such as that for a data server, includes many computing cores to increase computational processing capability, so that the number of computing cores per the area of the die is large, and the area of the die per computing core is small. To accommodate this, a high-density inductor having a larger inductance per unit area of the interposer is required.

US Patent Application Publication No. 2019/0279806 described above shows an example in which the substrate core mainly made of the organic material includes the conductive through hole (a conductor portion) and the magnetic sheath (a magnetic material portion) formed around the conductor portion and including the magnetic particles. In this case, the magnetic material portion is required to be formed at or below a heat resistant temperature of the organic material for the substrate core. As a typical technique satisfying the requirement, there is a technique of solidifying a resin in which the magnetic particles are dispersed. When the magnetic material portion includes the magnetic particles dispersed in the resin, however, a high permeability is less likely to be secured due to limitation of a filling factor of the magnetic particles (a proportion of the magnetic particles per volume). While the size of the inductor built in the interposer is required to be reduced in response to the above-mentioned densification of the interposer, a sufficient inductance is less likely to be secured when a dimension of each inductor is reduced by densification as permeability of the magnetic material portion is less likely to be increased as described above.

In WO 2007/129526 described above, the conductor (conductor portion) of the inductor is made of a plating film. In other words, plating is used as a method for forming the conductor portion. In this case, components of the magnetic body of the inductor are likely to enter into the conductor portion of the inductor in a plating solution. As a result, electrical characteristics (in particular, conductivity) of the conductor portion of the inductor greatly vary. Application of the inductor to an interposer thus easily increases variation of electrical characteristics (in particular, conductivity) of the interposer.

### SUMMARY

The aspects described below have been conceived to solve a problem as described above, and it is one object of them to provide an interposer enabling reduction in variation of electrical characteristics.

Aspect 1 is an interposer with a built-in inductor for mounting thereto a semiconductor element. The interposer includes an insulator substrate, a conductor portion, a magnetic material portion, and a wiring portion. The insulator substrate has a first surface, a second surface opposite the first surface in a thickness direction, and a through hole between the first surface and the second surface. The conductor portion extends through the through hole, and is made of a sintered material including sintered metal. The magnetic material portion surrounds the conductor portion within the through hole, is made of ceramics, is inorganically bonded to the conductor portion, and constructs the inductor with the conductor portion. The wiring portion includes a connecting via having a bottom surface electrically connected to the conductor portion. The bottom surface of the connecting via is spaced apart from the magnetic material portion.

Aspect 2 is the interposer according to Aspect 1, wherein the conductor portion is a non-hollow body.

Aspect 3 is the interposer according to Aspect 1 or 2, further including an intermediate terminal. The intermediate terminal contains sintered metal as a main component, faces each of the conductor portion and the magnetic material portion in the thickness direction, and is inorganically bonded to each of the conductor portion and the magnetic material portion. The connecting via is connected to the conductor portion with the intermediate terminal interposed therebetween.

Aspect 4 is the interposer according to Aspect 3, wherein the magnetic material portion contains a ferrite-based ceramic sintered body as a main component.

Aspect 5 is the interposer according to Aspect 1 or 2, wherein the connecting via is directly connected to the conductor portion.

Aspect 6 is the interposer according to Aspect 5, further including an insulator layer having a via hole in which the connecting via is disposed. The insulator layer separates the wiring portion and each of the magnetic material portion and the insulator substrate.

Aspect 7 is the interposer according to Aspect 6, wherein the via hole of the insulator layer is tapered toward the conductor portion.

Aspect 8 is the interposer according to Aspect 6 or 7, wherein the insulator layer contains an organic material.

Aspect 9 is the interposer according to any one of Aspects 1 to 8, wherein the conductor portion and the magnetic material portion are bonded together without an organic material interposed therebetween.

Aspect 10 is the interposer according to any one of Aspects 1 to 9, wherein the conductor portion and the magnetic material portion are sintered together.

Aspect 11 is the interposer according to any one of Aspects 1 to 10, wherein the wiring portion is a plating layer.

Aspect 12 is the interposer according to any one of Aspects 1 to 11, wherein the insulator substrate contains an organic material.

Aspect 13 is a method for manufacturing the interposer according to any one of Aspects 1 to 12, the method including: a) forming a chip as the inductor, the chip including the conductor portion extending along a direction of extension and the magnetic material portion surrounding the conductor portion; and b) disposing the chip in the through hole of the insulator substrate so that the direction of extension of the chip is along the thickness direction of the insulator substrate. a) includes: a1) preparing a first compact including magnetic material powder and having a planar shape with a main surface parallel to the direction of extension; a2) disposing, over the main surface of the first compact, at least one second compact including metal powder and extending along the direction of extension; a3) covering the second compact disposed over the main surface of the first compact with a third compact including magnetic material powder and having a planar shape to form a stack including the first compact, the second compact, and the third compact; and a4) firing the stack to form the magnetic material portion from the first compact and the third compact and form the conductor portion from the second compact.

According to the interposer according to each of Aspects 1 to 13 described above, first, the conductor portion is made of the sintered metal. Components of the magnetic material portion are thus less likely to enter into the conductor portion compared with a case where the conductor portion is made of another material, such as plating metal. Second, the bottom surface of the connecting via is spaced apart from the magnetic material portion. Entry of the components of the magnetic material portion into the connecting via is thereby avoided. In view of the foregoing, variation of electrical characteristics of the conductor portion and the connecting via included in an electrical path of the interposer is reduced. Variation of electrical characteristics of the interposer can thereby be reduced.

According to the method for manufacturing the interposer according to Aspect 13 described above, a dimension of the magnetic material portion in the thickness direction can easily be increased by adjusting a dimension of the second compact disposed in a2) in the direction of extension. An interposer including a magnetic material portion having a large dimension in the thickness direction can thus easily be manufactured compared with a manufacturing method for securing a dimension of the magnetic material portion in the thickness direction in response to the number of times a stacking step is repeated.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view schematically showing a configuration of electronic equipment.

FIG. 2 is a cross-sectional view illustrating electronic equipment in a modification of FIG. 1.

FIG. 3 is a schematic diagram illustrating a configuration of inductors built in a core substrate.

FIG. 4 is a circuit diagram illustrating an example of electrical connection between a first inductor and a second inductor illustrated in FIG. 3.

FIG. 5 is a partial cross-sectional view schematically showing a configuration of an interposer in Embodiment 1.

FIG. 6 is a partial cross-sectional view schematically showing a configuration of a core substrate of the interposer in FIG. 5.

FIG. 7 is a cross-sectional view schematically showing a configuration of an inductor chip of the core substrate in FIG. 6.

FIG. 8 is a perspective view schematically showing a configuration of the inductor chip in FIG. 7.

FIG. 9 is a flowchart schematically showing a method for manufacturing the interposer in Embodiment 1.

FIG. 10 is a partial cross-sectional view schematically showing a step of inserting the inductor chip as one step in FIG. 9.

FIG. 11 is a perspective view schematically showing one step for forming the inductor chip in the method for manufacturing the interposer in FIG. 9.

FIG. 12 is a perspective view schematically showing one step for forming the inductor chip in the method for manufacturing the interposer in FIG. 9.

FIG. 13 is a perspective view schematically showing one step for forming the inductor chip in the method for manufacturing the interposer in FIG. 9.

FIG. 14 is a perspective view schematically showing one step for forming the inductor chip in the method for manufacturing the interposer in FIG. 9.

FIG. 15 is a perspective view schematically showing one step for forming the inductor chip in the method for manufacturing the interposer in FIG. 9.

FIG. 16 is a perspective view schematically showing one step for forming the inductor chip in the method for manufacturing the interposer in FIG. 9.

FIG. 17 is a perspective view schematically showing one step for forming the inductor chip in the method for manufacturing the interposer in FIG. 9.

FIG. 18 is a partial cross-sectional view schematically showing a configuration of an interposer in Embodiment 2.

FIG. 19 is a partial cross-sectional view schematically showing a configuration of an interposer in Embodiment 3.

### DESCRIPTION OF THE PREFERRED EMBODIMENTS

Embodiments of the present invention will be described below based on the drawings.

### <Preliminary Description>

Technology that can be combined with each of embodiments described below will be described first below.

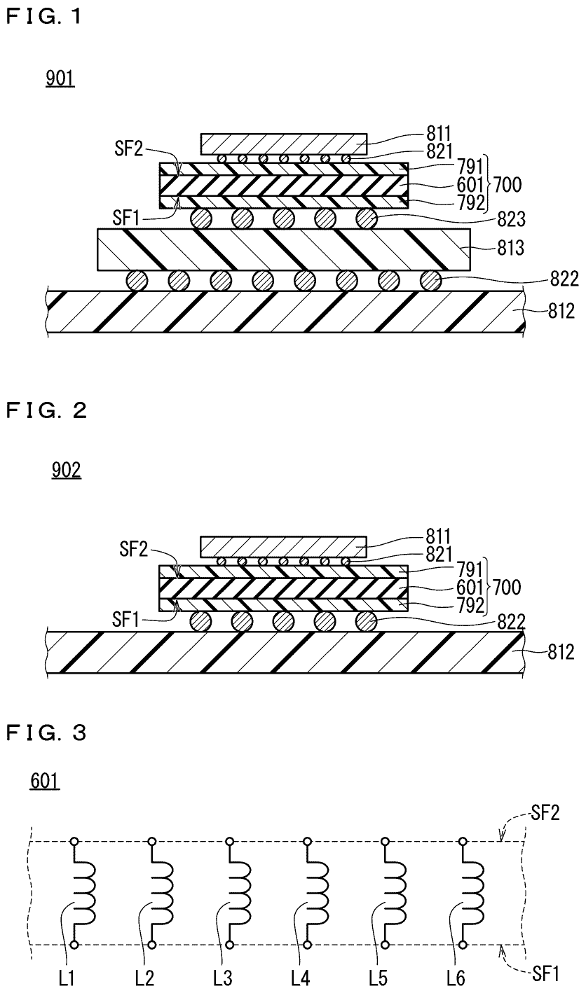

FIG. 1 is a cross-sectional view schematically showing a configuration of electronic equipment 901. The electronic equipment 901 includes an interposer 700, a semiconductor element 811 (die), a motherboard 812, and a package substrate 813. The interposer 700 includes a core substrate 601, a wiring layer 791, and a wiring layer 792.

The wiring layer 792 and the wiring layer 791 are respectively stacked over one surface and the other surface (specifically, directly or indirectly over a first surface SF1 and a second surface SF2 described below) of the core substrate 601. The wiring layer 791 and the wiring layer 792 may be stacked over the core substrate 601 by build-up or sputtering, or may be joined as separate wiring boards.

The wiring layer 791 is preferably a multilayer wiring layer configured to have a wiring dimension (e.g., a line and space (L/S) dimension) reduced from a side facing the core substrate 601 to a side facing the semiconductor element 811. The interposer 700 to which the semiconductor element 811 having a small terminal pitch can be mounted can thereby be constructed even if a wiring (L/S) dimension of the core substrate 601 is not so fine. Specifically, the wiring layer 791 may be a stack of a normal wiring layer facing the core substrate 601 and a fine wiring layer facing the semiconductor element 811. The normal wiring layer may be formed by providing a wiring structure to a plate-

like organic material member (e.g., an epoxy-based member) or inorganic material member (e.g., a low temperature co-fired ceramics (LTCC) member or a non-magnetic ferrite member). Cu plating is used to form the wiring structure to the organic material member, for example. To form the wiring structure to the inorganic material member, the wiring structure is formed by firing of Ag (silver), AgPd (silver palladium), or Cu (copper) simultaneously with formation of the inorganic material member in a firing step.

The fine wiring layer is preferably formed by providing a wiring structure to a plate-like organic material member (e.g., an epoxy-based or a polyimide-based member) in terms of ease of formation of fine wiring. Cu plating is used to form the wiring structure to the organic material member, for example.

The semiconductor element 811 is mounted to the wiring layer 791 of the interposer 700. The semiconductor element 811 is connected to the wiring layer 791 of the interposer 700 by solder balls 821, for example. The semiconductor element 811 may be an integrated circuit (IC) chip. In particular, when the IC chip is a processor chip including a plurality of computing cores, the above-mentioned voltage regulator can be constructed using an inductor described below.

The interposer 700 is mounted to the package substrate 813 by joining the wiring layer 792 to the package substrate 813. The joining is achieved by solder balls 823, for example. The package substrate 813 is mounted to the motherboard 812, for example, by joining using solder balls 822.

According to the foregoing, an element side (a side facing the semiconductor element 811) of the interposer 700 is constructed by the wiring layer 791, and a substrate side (a side facing the package substrate 813 and the motherboard 812) of the interposer 700 is constructed by the wiring layer 792. A plurality of terminals (not illustrated) are provided to each of the element side and the substrate side of the interposer 700. A terminal pitch on the element side may be smaller than a terminal pitch on the substrate side, and, in this case, the interposer 700 has a function of transforming the terminal pitch. As a modification, either or both of the wiring layer 791 and the wiring layer 792 may be omitted in some applications of the interposer.

FIG. 2 is a cross-sectional view illustrating electronic equipment 902 in a modification of the electronic equipment 901 (FIG. 1). In the electronic equipment 902, the interposer 700 is joined to the motherboard 812 without the package substrate 813 (FIG. 1) interposed therebetween, and the joining is achieved by the solder balls 822, for example.

FIG. 3 is a schematic diagram illustrating a configuration of inductors built in the core substrate 601. In the core substrate 601, a plurality of inductors L1 and L2 are built, inductors L3 to L6 and the like may further be built, and any number of inductors may be built. While a configuration of the inductors L1 and L2 will be described in detail below, the inductors L3 to L6 and the like may have a similar configuration.

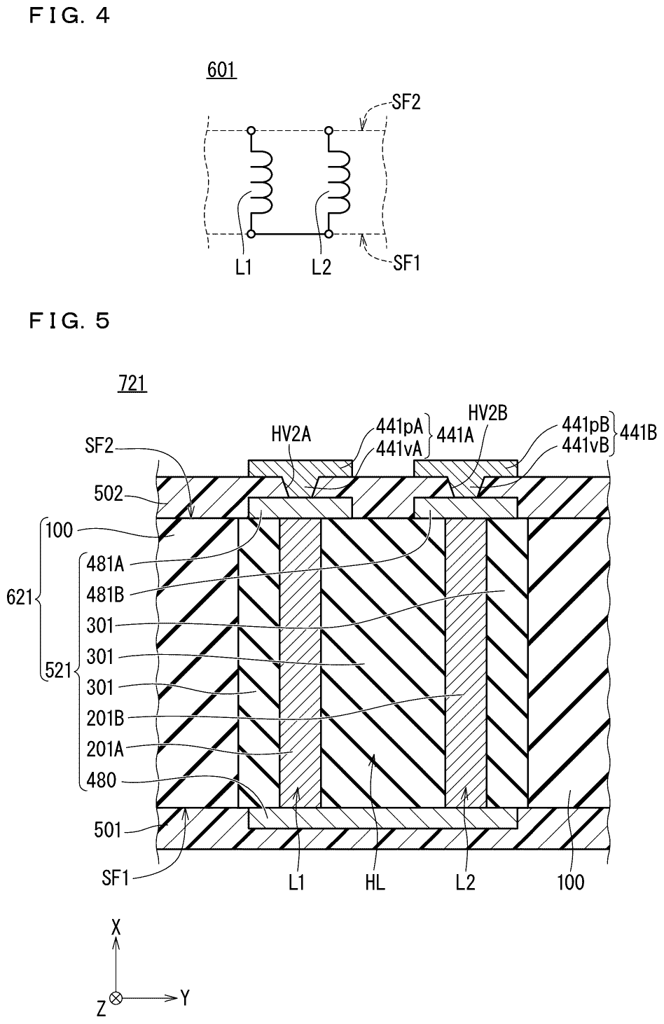

FIG. 4 is a circuit diagram illustrating an example of electrical connection between the inductors L1 and L2 illustrated in FIG. 3. In this example, the inductors L1 and L2 are connected in series to constitute an inductor having a combined inductance larger than an inductance of each of the inductors L1 and L2, and opposite ends of the inductor are arranged on the second surface SF2 to face the semiconductor element 811 (FIG. 1). The inductor having a sufficiently large inductance can thereby easily be connected to the semiconductor element 811. Electrical connection between the plurality of inductors built in the core substrate is not limited to that illustrated in FIG. 4, and may be designed as appropriate according to the application of the core substrate. A series structure of any number of inductors, a parallel structure of any number of inductors, or a combination thereof may thus be constructed.

### Embodiment 1

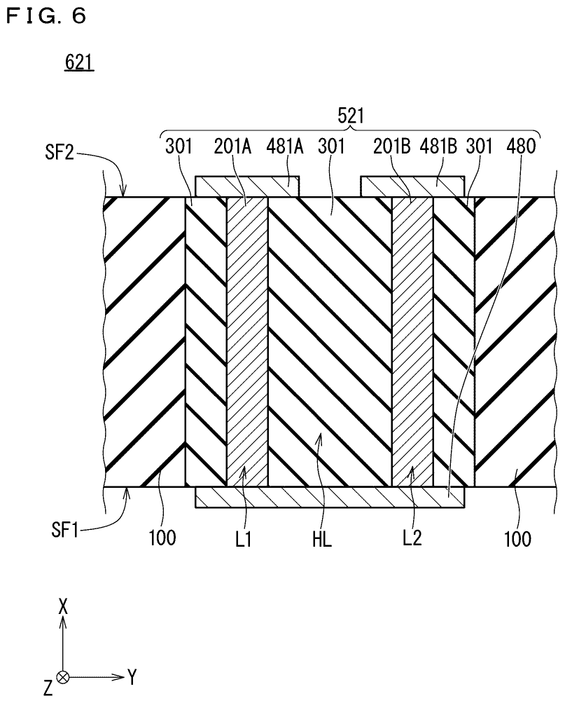

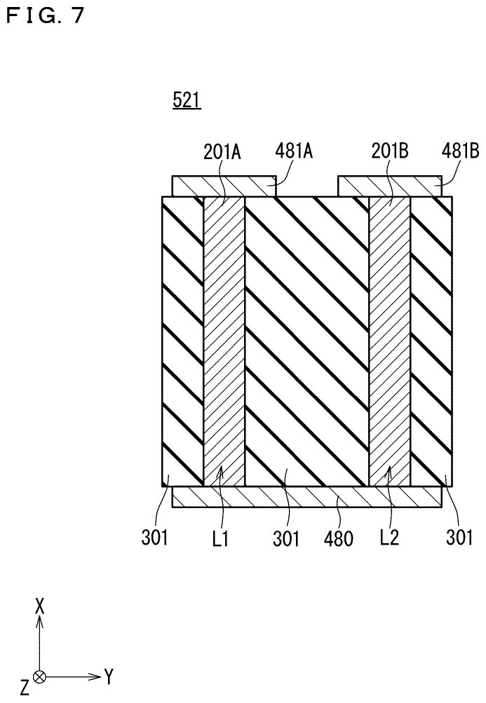

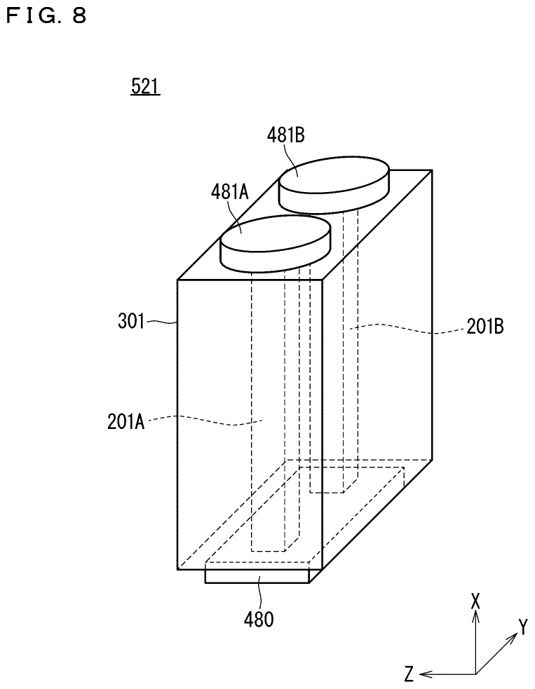

FIG. 5 is a partial cross-sectional view schematically showing a configuration of an interposer 721 in Embodiment 1. FIG. 6 is a partial cross-sectional view schematically showing a configuration of a core substrate 621 of the interposer 721 (FIG. 5). FIG. 7 is a cross-sectional view schematically showing a configuration of an inductor chip 521 (a chip as an inductor) of the core substrate 621 (FIG. 6). FIG. 8 is a perspective view schematically showing a configuration of the inductor chip 521 (FIG. 7). The interposer 721 has a similar application to that of the interposer 700 (FIGS. 1 and 2) described above. In other words, the interposer 721 is for mounting thereto the semiconductor element 811 (FIGS. 1 and 2), and the inductors L1 and L2 are built in the core substrate 621 of the interposer 721. More inductors may be built in the core substrate 621 as described in Preliminary Description above.

The interposer 721 includes the core substrate 621 corresponding to the core substrate 601 (FIGS. 1 and 2), members corresponding to the wiring layer 791 (FIGS. 1 and 2), and members corresponding to the wiring layer 792 (FIGS. 1 and 2). The members corresponding to the wiring layer 791 (FIGS. 1 and 2) include an insulator layer 502, a wiring portion 441A, and a wiring portion 441B. The members corresponding to the wiring layer 792 (FIGS. 1 and 2) include an insulator layer 501. The members corresponding to the wiring layer 791 and the wiring layer 792 (FIGS. 1 and 2) are not limited to the members illustrated in FIG. 5, and may be added as appropriate in response to the configuration of the electronic equipment 901 (FIG. 1) or the electronic equipment 902 (FIG. 2). The members may be added by build-up or sputtering, or may be added by joining other members, for example.

The core substrate 621 includes an insulator substrate 100 and the inductor chip 521. The inductor chip 521 includes conductor portions 201A and 201B, a magnetic material portion 301, and intermediate terminals 481A and 481B.

The insulator substrate 100 may be made of any of an organic material, an inorganic material, and a mixed material thereof, and is a resin substrate or a ceramic substrate, for example. The insulator substrate 100 may thus contain the organic material. The insulator substrate 100 has the first surface SF1 and the second surface SF2 opposite the first surface SF1 in a thickness direction. The insulator substrate 100 has a through hole HL between the first surface SF1 and the second surface SF2.

The conductor portion 201A and the conductor portion 201B each extend through the through hole HL. The conductor portion 201A and the conductor portion 201B may each be a non-hollow body. In other words, the conductor portion 201A and the conductor portion 201B are each not required to have a hollow interior. Electrical resistance of each of the conductor portions 201A and 201B can thereby be reduced. The conductor portions 201A and 201B are made of a sintered material including sintered metal. The sintered metal includes at least one of Ag, AgPd, and Cu, for example. The sintered material for the conductor portions 201A and 201B may include a ceramic material as a material having a lower conductivity than the sintered metal to the extent that its function as electrical wiring is maintained. A proportion of the ceramic material to the sintered metal is preferably 5 vol % or more and 30 vol % or less. The material for the conductor portions 201A and 201B includes the ceramic material, so that bonding between the magnetic material portion 301 and each of the conductor portions 201A and 201B can be enhanced. The ceramic material preferably has a particle size of 0.5 μm or more and 10 μm or less. Examples of the ceramic material include alumina, zirconia, magnesium oxide, and titanium oxide.

The magnetic material portion 301 surrounds the conductor portions 201A and 201B within the through hole HL. In Embodiment 1, the magnetic material portion 301 constructs the inductor L1 and the inductor L2 (FIG. 4) respectively with the conductor portion 201A and the conductor portion 201B. The magnetic material portion 301 is inorganically bonded to each of the conductor portion 201A and the conductor portion 201B. In other words, an inorganic material for each of the conductor portions 201A and 201B and an inorganic material for the magnetic material portion 301 are bonded together without an organic material interposed therebetween, and, specifically, are sintered together. The magnetic material portion 301 is made of ceramics (a ceramic sintered body). The magnetic material portion 301 is not required to contain an organic component. To reduce the volume of the inductor, a magnetic material for the magnetic material portion 301 desirably has a high permeability, and the magnetic material portion 301 preferably has a compactness of 70% or more. To reduce an electrical loss of the inductor, the magnetic material for the magnetic material portion 301 is desirably a soft magnetic material having a small magnetic loss at a high frequency, and is desirably a soft magnetic material having a magnetic loss tangent of 0.1 or less at a frequency of 100 MHZ, for example. To reduce a magnetic loss at a high frequency, the magnetic material for the magnetic material portion 301 desirably has a high volume electrical resistivity, and, specifically, is desirably an electrical insulator. The magnetic material portion 301 preferably contains a ferrite-based ceramic sintered body as a main component. A crystalline structure of a material for the ferrite-based ceramic sintered body is preferably a spinel structure in terms of ease of manufacture, and Ni—Zn-based ferrite or Ni—Zn—Cu-based ferrite is used, for example. Hexagonal ferrite having a c-axis orientation along the thickness direction (a vertical direction in FIG. 5) may be used in terms of obtainment of a higher permeability.

The intermediate terminal 481A and the intermediate terminal 481B contain sintered metal as a main component, and may contain a small amount of glass component in addition to the sintered metal. The sintered metal contains Ag, AgPd, or Cu as a main component, for example. The intermediate terminal 481A faces each of the conductor portion 201A and the magnetic material portion 301 in the thickness direction, and is inorganically bonded to each of the conductor portion 201A and the magnetic material portion 301. Similarly, the intermediate terminal 481B faces each of the conductor portion 201B and the magnetic material portion 301 in the thickness direction, and is inorganically bonded to each of the conductor portion 201B and the magnetic material portion 301.

The wiring portion 441A and the wiring portion 441B may each be a plating layer. The wiring portion 441A includes a wiring pattern 441pA and a connecting via 441vA. A planar layout (layout in a YZ plane in FIG. 5) of the wiring pattern 441pA may be designed according to an application of the interposer 721. Similarly, the wiring portion 441B includes a wiring pattern 441pB and a connecting via 441vB. A planar layout (layout in the YZ plane in FIG. 5) of the wiring pattern 441pB may be designed according to the application of the interposer 721.

The connecting via 441vA has a bottom surface electrically connected to the conductor portion 201A. In Embodiment 1, the connecting via 441vA is connected to the conductor portion 201A with the intermediate terminals 481A interposed therebetween. To obtain the connection, the bottom surface of the connecting via 441vA is directly connected to the intermediate terminal 481A. Similarly, the connecting via 441vB has a bottom surface electrically connected to the conductor portion 201B. In Embodiment 1, the connecting via 441vB is connected to the conductor portion 201B with the intermediate terminal 481B interposed therebetween. To obtain the connection, the bottom surface of the connecting via 441vB is directly connected to the intermediate terminal 481B.

Each of the connecting via 441vA and the connecting via 441vB is spaced apart from the magnetic material portion 301. The bottom surface of each of the connecting via 441vA and the connecting via 441vB is thus spaced apart from the magnetic material portion 301. Each of the connecting via 441vA and the connecting via 441vB is spaced apart from the insulator substrate 100. The bottom surface of each of the connecting via 441vA and the connecting via 441vB is thus spaced apart from the insulator substrate 100. The insulator layer 502 has a via hole HV2A and a via hole HV2B in which the connecting via 441vA and the connecting via 441vB are respectively arranged. The insulator layer 502 may separate the magnetic material portion 301 and each of the wiring portion 441A and the wiring portion 441B. The insulator layer 502 may also separate the insulator substrate 100 and each of the wiring portion 441A and the wiring portion 441B. The insulator layer 502 has the via hole HV2A and the via hole HV2B to respectively expose the intermediate terminal 481A and the intermediate terminal 481B, but may respectively cover the intermediate terminal 481A and the intermediate terminal 481B locally around the via hole HV2A and the via hole HV2B. The via hole HV2A and the via hole HV2B may respectively be tapered toward the conductor portion 201A and the conductor portion 201B (downward in FIG. 5). The insulator layer 502 contains an organic material, and is an epoxy-based member, for example.

A connecting portion 480 electrically connects the conductor portion 201A and the conductor portion 201B on the first surface SF1 of the insulator substrate 100. The inductor L1 and the inductor L2 are thereby connected in series (see the circuit diagram of FIG. 4). A material for the connecting portion 480 may be similar to a material for the intermediate terminal 481A and the intermediate terminal 481B.

The insulator layer 501 covers the connecting portion 480 in Embodiment 1. A material for the insulator layer 501 may be similar to a material for the insulator layer 502.

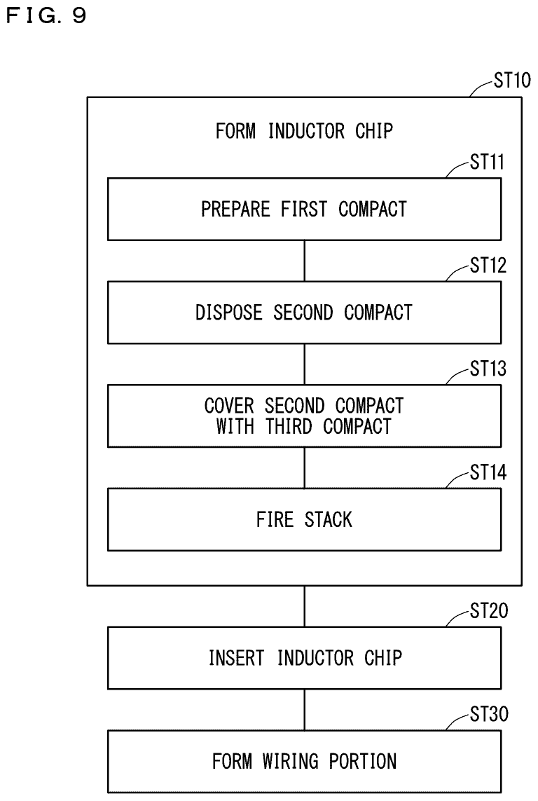

FIG. 9 is a flowchart schematically showing a method for manufacturing the interposer 721 (FIG. 5). First, in step ST10, the inductor chip 521 (FIGS. 7 and 8) is formed. Next, in step ST20, the inductor chip 521 is inserted into the insulator substrate 100 to obtain the core substrate 621 (FIG. 6). Next, in step ST30, the wiring portion 441A, the wiring portion 441B, the insulator layer 502, and the insulator layer 501 (FIG. 5) are formed by build-up, for example. The wiring portions 441A and 441B may each be the plating layer. In this case, the wiring portions 441A and 441B and the insulator layer 502 may be formed by a semi-additive method, and may generally be formed as described below, for example. An organic insulating film as the insulator layer 502 not having the via holes HV2A and HV2B yet is attached to the second surface SF2 of the core substrate 621. Next, the via holes HV2A and HV2B are formed by laser processing. Next, a seed layer is formed on a surface of the insulator layer 502 including an inner surface of each of the via holes HV2A and HV2B by electroless copper plating. Next, a plating resist exposing regions in which the wiring patterns 441pA and 441pB of the wiring portions 441A and 441B are to be formed is formed over the insulator layer 502. Next, electrolytic copper plating is performed using the seed layer and the plating resist described above. Next, the plating resist is stripped. The wiring portions 441A and 441B are thereby formed.

The interposer 721 can be obtained by the above-mentioned manufacturing method. The above-mentioned manufacturing method will be further described in detail below.

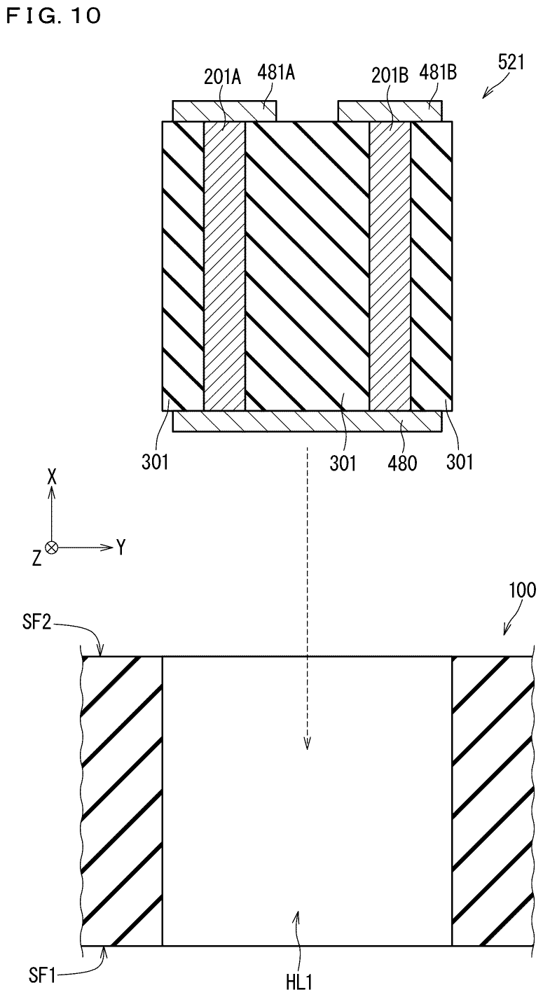

FIG. 10 is a partial cross-sectional view schematically showing step ST20 (FIG. 9). The inductor chip 521 formed in step ST10 includes the conductor portion 201A and the conductor portion 201B extending along a direction of extension and the magnetic material portion 301 surrounding the conductor portion 201A and the conductor portion 201B. The direction of extension is a longitudinal direction of each of the conductor portion 201A and the conductor portion 201B, and corresponds to a vertical direction in FIG. 10. In step ST20, the inductor chip 521 is disposed in the through hole HL of the insulator substrate 100 so that the direction of extension of the inductor chip 521 is along the thickness direction (an X direction in FIG. 10) of the insulator substrate 100. The disposing step can be performed by inserting the inductor chip 521 into the through hole HL of the insulator substrate 100 with the direction of extension of the inductor chip 521 being along the thickness direction of the insulator substrate 100 as indicated by an arrow (FIG. 10). The inductor chip 521 and the insulator substrate 100 may be fixed using an adhesive (not illustrated).

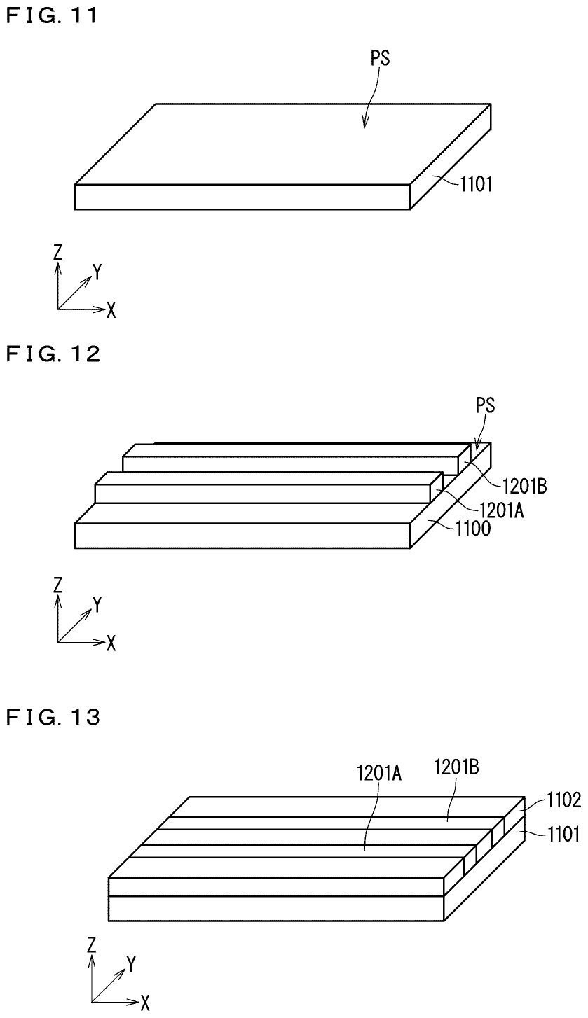

FIGS. 11 to 17 are perspective views schematically showing steps sequentially performed for step ST10 (FIG. 9). These steps will be described below.

With reference to FIG. 11, in step ST11 (FIG. 9), a first compact 1101 is prepared. The first compact 1101 includes magnetic material powder. The magnetic material powder is ferrite powder, for example. The first compact 1101 may contain an organic binder to compact the magnetic material powder. The first compact 1101 has a planar shape with a main surface PS (main surface parallel to an XY plane in FIG. 11) parallel to the direction of extension (an X direction in FIG. 11). The planar shape has a thickness of 150 μm, for example.

With reference to FIG. 12, in step ST12 (FIG. 9), second compacts 1201A and 1201B are arranged over the main surface PS of the first compact 1101. The second compacts 1201A and 1201B include metal powder. The arrangement step can be performed by printing a paste including Ag powder, AgPd powder, or Cu powder and an organic binder, for example. While two second compacts, that is, the second compacts 1201A and 1201B are arranged in Embodiment 1, any number of second compacts may be arranged as a modification. The second compacts 1201A and 1201B each extend along the direction of extension (X direction in each of FIGS. 11 and 12). The second compacts 1201A and 1201B each have a thickness of 150 μm, for example.

With reference to FIG. 13, a compact 1102 may be disposed to reduce asperities due to the second compacts 1201A and 1201B over the main surface PS of the first compact 1101. The compact 1102 includes magnetic material powder. The magnetic material powder is ferrite powder, for example. The compact 1102 may contain an organic binder to compact the magnetic material powder. The disposing step can be performed by printing a paste including the magnetic material powder and the organic binder. The compact 1102 has a thickness of 150 μm, for example. The step of arranging the second compact 1201A and the second compact 1201B and the step of disposing the compact 1102 may be performed in any order.

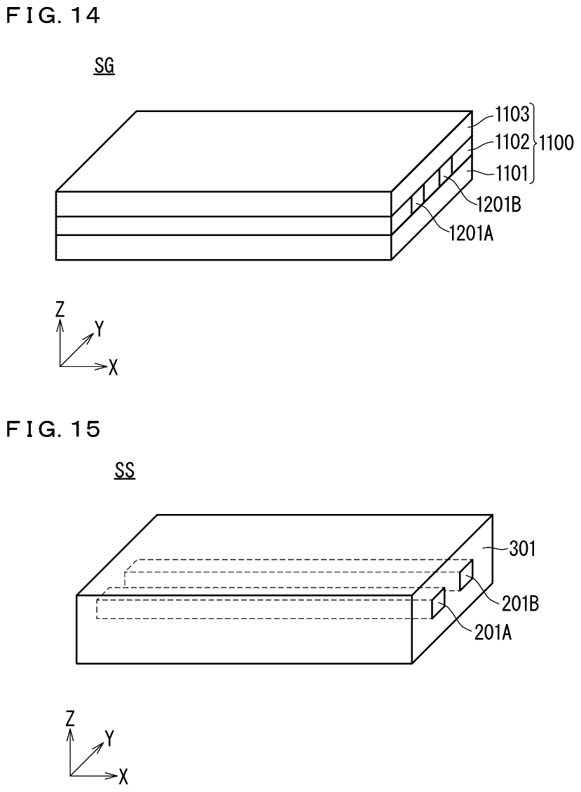

With reference to FIG. 14, in step ST13 (FIG. 9), the second compacts 1201A and 1201B arranged over the main surface PS (see FIG. 12) of the first compact 1101 are covered with a third compact 1103. The third compact 1103 includes magnetic material powder, and has a planar shape as with the first compact 1101. A stack SG including the first compact 1101, the second compacts 1201A and 1201B, and the third compact 1103 is thereby formed. The stack SG may include the above-mentioned compact 1102. In forming the stack SG, pressing at a pressure of approximately 4 MPa to 10 MPa may be performed, and, in this case, heating at a temperature of approximately 100° C. may be performed.

With reference to FIG. 15, in step ST14 (FIG. 9), the stack SG (FIG. 14) is fired to obtain a sintered body SS. By the firing, the magnetic material portion 301 is formed from the first compact 1101, the compact 1102, and the third compact 1103. The conductor portions 201A and 201B are respectively formed from the second compacts 1201A and 1201B.

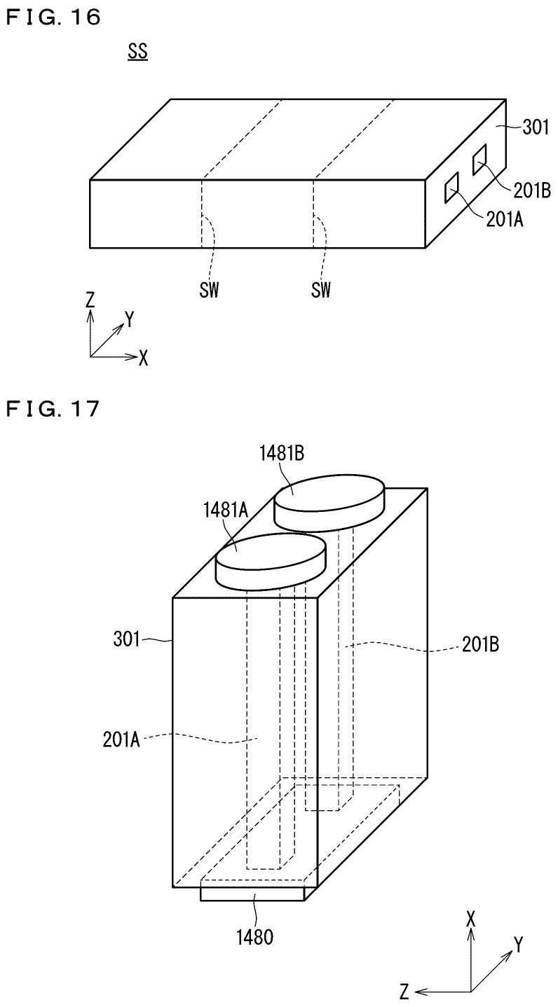

With reference to FIG. 16, the sintered body SS may be cut to adjust a length (a dimension in the X direction in FIG. 16) of the sintered body SS as appropriate as indicated by dashed lines SW in FIG. 16. The number of sintered bodies SS can be increased by the cutting.

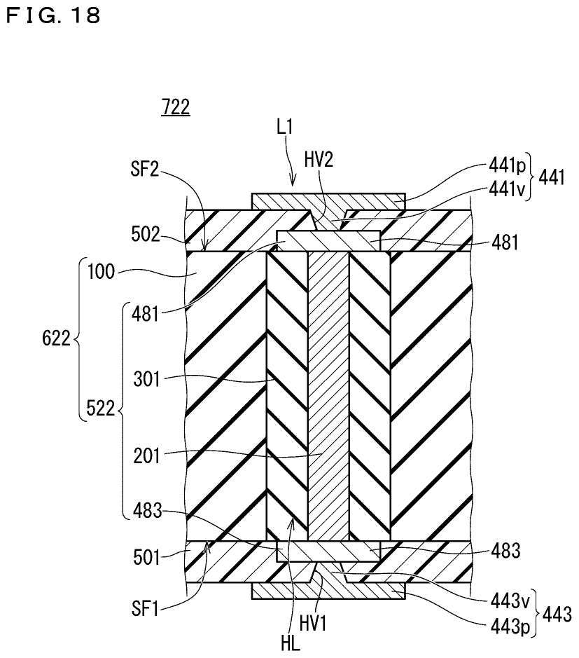

With reference to FIG. 17, a fourth compact 1481A and a fourth compact 1481B are arranged to respectively be in contact with one end of the conductor portion 201A and one end of the conductor portion 201B. A fifth compact 1480 is disposed to be in contact with both of the other end of the conductor portion 201A and the other end of the conductor portion 201B. The fourth compacts 1481A and 1481B and the fifth compact 1480 include metal powder. The arrangement step can be performed by printing a paste including Ag powder, an organic binder, and a small amount of glass, for example. The fourth compacts 1481A and 1481B and the fifth compact 1480 each have a thickness of 20 μm, for example. The fourth compacts 1481A and 1481B each have a circular shape having a diameter of 260 μm in the YZ plane, for example. Next, the fourth compacts 1481A and 1481B and the fifth compact 1480 are fired. The firing is performed in the atmosphere at a temperature of 600° C. to 800° C., for example. By the firing, the intermediate terminal 481A, the intermediate terminal 481B, and the connecting portion 480 (FIG. 8) are formed respectively from the fourth compact 1481A, the fourth compact 1481B, and the fifth compact 1480.

This completes step ST10 (FIG. 9) of forming the inductor chip 521 (FIG. 8). According to the above-mentioned manufacturing method, an outline of the magnetic material portion 301 of the inductor chip 521 has a thickness (dimension in the X direction) of 1 mm, a width (dimension in a Z direction) of 360 μm, and a depth (dimension in a Y direction) of 720 μm, for example. The conductor portion 201A and the conductor portion 201B of the inductor chip 521 are formed respectively from the second compact 1201A and the second compact 1201B (FIG. 12), and they are formed over the main surface PS of the first compact 1101. With this, the conductor portions 201A and 201B have flat surfaces parallel to the thickness direction (X direction). More specifically, in cross section perpendicular to the thickness direction (X direction in FIG. 8), the conductor portions 201A and 201B may each have a rectangular shape, and each have a square shape 120 μm on a side, for example.

According to the interposer 721 (FIG. 5) in Embodiment 1, first, the conductor portions 201A and 201B are made of the sintered metal. Components of the magnetic material portion 301 are thus less likely to enter into the conductor portions 201A and 201B compared with a case where the conductor portions 201A and 201B are made of another material, such as plating metal. Second, the bottom surface of each of the connecting vias 441vA and 441vB is spaced apart from the magnetic material portion 301. Entry of the components of the magnetic material portion 301 into the connecting vias 441vA and 441vB is thereby avoided. In view of the foregoing, variation of electrical characteristics (in particular, conductivity) of the conductor portions 201A and 201B and the connecting vias 441vA and 441vB included in an electrical path of the interposer 721 is reduced. Variation of electrical characteristics of the interposer 721 can thereby be reduced.

The magnetic material portion 301 (FIG. 5) is not made of a resin in which magnetic particles are dispersed, but is made of a ceramic sintered body. Permeability of the magnetic material portion 301 can thereby sufficiently be increased by densely sintering the ceramics. The inductor having a large inductance per unit area can thus be built in the core substrate 621.

According to the method for manufacturing the interposer 721 according to Embodiment 1, a dimension of the magnetic material portion 301 in the thickness direction can easily be increased by adjusting dimensions of the second compacts 1201A and 1201B arranged in step ST12 (FIG. 9) in the direction of extension (X direction in FIG. 12). The interposer 721 including the magnetic material portion 301 having a large dimension in the thickness direction can thus easily be manufactured compared with a manufacturing method for securing the dimension of the magnetic material portion 301 (FIG. 5) in the thickness direction (X direction in FIG. 5) in response to the number of times a stacking step is repeated.

### Embodiment 2

FIG. 18 is a partial cross-sectional view schematically showing a configuration of an interposer 722 in Embodiment 2. The interposer 722 includes a core substrate 622. The core substrate 622 includes an inductor chip 522. The inductor chip 522 includes a conductor portion 201 similar to one of the conductor portions 201A and 201B of the inductor chip 521 (FIG. 5: Embodiment 1) in place of the conductor portions 201A and 201B, includes an intermediate terminal 481 similar to one of the intermediate terminals 481A and 481B of the inductor chip 521 in place of the intermediate terminals 481A and 481B, and includes a wiring portion 441 similar to one of the wiring portions 441A and 441B of the inductor chip 521 in place of the wiring portions 441A and 441B. The wiring portion 441 includes a wiring pattern 441p and a connecting via 441v. The insulator layer 502 has a via hole HV2 similar to one of the via holes HV2A and HV2B in place of the via holes HV2A and HV2B. The connecting via 441v is disposed in the via hole HV2. The inductor chip 522 also includes an intermediate terminal 483 having a similar configuration to the intermediate terminal 481 in place of the connecting portion 480 (FIG. 5: Embodiment 1). The interposer 722 correspondingly includes a wiring portion 443 having a similar configuration to the wiring portion 441. The wiring portion 443 includes a wiring pattern 443p and a connecting via 443v. The insulator layer 501 has a via hole HV1 in which the connecting via 443v is disposed.

A substantially similar effect to that obtained in Embodiment 1 described above can be obtained in Embodiment 2.

### Embodiment 3

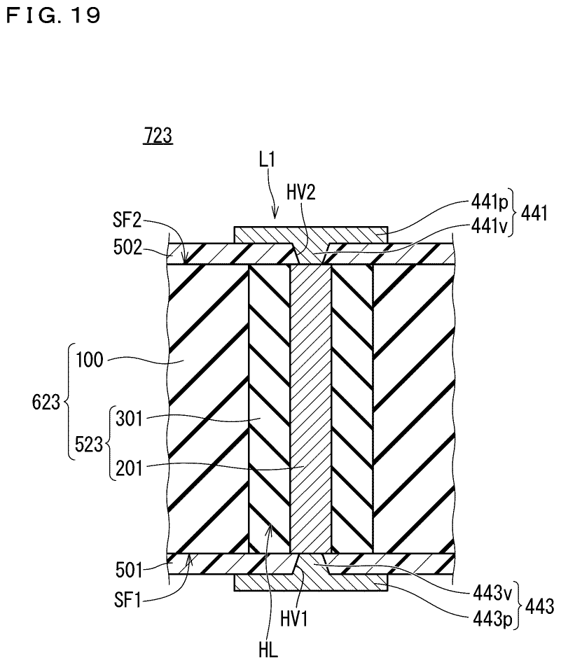

FIG. 19 is a partial cross-sectional view schematically showing a configuration of an interposer 723 in Embodiment 3. The interposer 723 includes a core substrate 623. The core substrate 623 includes an inductor chip 523. The interposer 723 has a configuration in which the intermediate terminals 481 and 483 of the interposer 722 (FIG. 18) are omitted. Thus, in Embodiment 3, each of the connecting via 441v and the connecting via 443v is directly connected to the conductor portion 201. The insulator layer 502 separates the wiring portion 441 and each of the magnetic material portion 301 and the insulator substrate 100. Similarly, the insulator layer 501 separates the wiring portion 443 and each of the magnetic material portion 301 and the insulator substrate 100.

Each of the via hole HV1 and the via hole HV2 may be tapered toward the conductor portion 201. Cross-sectional areas of the connecting vias 441v and 443v can thereby be increased at positions spaced apart from the magnetic material portion 301 while contact of the connecting vias 441v and 443v with the magnetic material portion 301 is avoided. Electrical resistance of the connecting vias 441v and 443v can thereby be suppressed.

A substantially similar effect to that obtained in Embodiment 1 described above can be obtained in Embodiment 3. The configuration of the interposer can be simplified by omitting the intermediate terminals 481 and 483. When it is important to secure electrical connection to end surfaces of the conductor portion 201 with large areas, however, Embodiment 2 in which the intermediate terminals 481 and 483 are included is preferable. As a modification of Embodiment 1, the intermediate terminals 481A and 481B may be omitted as in Embodiment 3.

What is claimed is:

1. An interposer with a built-in inductor, the interposer being for mounting thereto a semiconductor element, the interposer comprising:
an insulator substrate having a first surface, a second surface opposite the first surface in a thickness direction, and a through hole between the first surface and the second surface;
a conductor portion extending through the through hole, and made of a sintered material including sintered metal;
a magnetic material portion surrounding the conductor portion within the through hole, made of ceramics, inorganically bonded to the conductor portion, and constructing the inductor with the conductor portion; and
a wiring portion including a connecting via having a bottom surface electrically connected to the conductor portion, wherein
the bottom surface of the connecting via is spaced apart from the magnetic material portion.

2. The interposer according to claim 1, wherein
the conductor portion is a non-hollow body.

3. The interposer according to claim 1, further comprising
an intermediate terminal containing sintered metal as a main component, facing each of the conductor portion and the magnetic material portion in the thickness direction, and inorganically bonded to each of the conductor portion and the magnetic material portion, wherein
the connecting via is connected to the conductor portion with the intermediate terminal interposed therebetween.

4. The interposer according to claim 1, wherein
the magnetic material portion contains a ferrite-based ceramic sintered body as a main component.

5. The interposer according to claim 1, wherein
the connecting via is directly connected to the conductor portion.

6. The interposer according to claim 5, further comprising an insulator layer having a via hole in which the connecting via is disposed, wherein
the insulator layer separates the wiring portion and each of the magnetic material portion and the insulator substrate.

7. The interposer according to claim 6, wherein
the via hole of the insulator layer is tapered toward the conductor portion.

8. The interposer according to claim 6, wherein
the insulator layer contains an organic material.

9. The interposer according to claim 1, wherein
the conductor portion and the magnetic material portion are bonded together without an organic material interposed therebetween.

10. The interposer according to claim 1, wherein
the conductor portion and the magnetic material portion are sintered together.

11. The interposer according to claim 1, wherein
the wiring portion is a plating layer.

12. The interposer according to claim 1, wherein
the insulator substrate contains an organic material.

13. A method for manufacturing the interposer according to claim 1, the method comprising:
a) forming a chip as the inductor, the chip including the conductor portion extending along a direction of extension and the magnetic material portion surrounding the conductor portion; and
b) disposing the chip in the through hole of the insulator substrate so that the direction of extension of the chip is along the thickness direction of the insulator substrate, wherein
a) comprises:
a1) preparing a first compact including magnetic material powder and having a planar shape with a main surface parallel to the direction of extension;
a2) disposing, over the main surface of the first compact, at least one second compact including metal powder and extending along the direction of extension;
a3) covering the second compact disposed over the main surface of the first compact with a third compact including magnetic material powder and having a planar shape to form a stack including the first compact, the second compact, and the third compact; and
a4) firing the stack to form the magnetic material portion from the first compact and the third compact and form the conductor portion from the second compact.
